(19) United States
(12) Patent Application Publication
(10) Pub. No.: US 2018/0324912 A1
(43) Pub. Date: Nov. 8, 2018

(54) DISPLAY DEVICE

(71) Applicants: LITE-ON ELECTRONICS (GUANGZHOU) LIMITED, Guangzhou (CN); LITE-ON TECHNOLOGY CORPORATION, Taipei (TW)

(72) Inventor: Peng-Kai HSU, Taipei (TW)

(21) Appl. No.: 15/854,019

(22) Filed: Dec. 26, 2017

Related U.S. Application Data
(60) Provisional application No. 62/492,978, filed on May 2, 2017.

(51) Int. Cl. H05B 33/08; H01L 25/16; G09G 3/34; G09G 3/32

(52) U.S. Cl. CPC H05B 33/0815; H05B 33/0812; H05B 33/0827; G09G 3/32; H05B 33/089; H01L 25/167; G09G 3/3406; H05B 33/0845

(57) ABSTRACT

A display device includes a first light-emitting diode (LED) module, a second LED module, a first main-switch, a second main-switch and a plurality of branch-switches. The first LED module comprises a plurality of first LED units. The second LED module comprises a plurality of second LED units. The first main-switch is coupled to the first LED units. The second main-switch is coupled to the second LED units. The branch-switches are coupled to the first LED units and the second LED units.

This application claims the benefit of U.S. provisional application Ser. No. 62/492,978, filed May 2, 2017, the subject matter of which is incorporated herein by reference.

### BACKGROUND OF THE INVENTION

### Field of the Invention

The invention relates in general to a display device, and more particularly to a display device having a plurality of switches.

### Description of the Related Art

Conventional one seven-segment display has seven segments and accordingly needs seven switches to control the seven segments respectively. If a display device includes four seven-segment displays, it needs twenty-eight switches to control twenty-eight segments of the four seven-segment displays. However, the more the number of the switches is, the more the number of the required LED driver is. In general, the four seven-segment displays need two LED drivers, and it accordingly increase cost of LED drivers and circuit layout complexity.

### SUMMARY OF THE INVENTION

According to one embodiment of the invention, a display device is provided. The display device includes a first light-emitting diode (LED) module, a second LED module, a first main-switch, a second main-switch and a plurality of branch-switches. The first LED module comprises a plurality of first LED units. The second LED module comprises a plurality of second LED units. The first main-switch is coupled to the first LED units. The second main-switch is coupled to the second LED units. The branch-switches are coupled to the first LED units and the second LED units.

According to another embodiment of the invention, a display device is provided. The display device includes a first LED module, a second LED module, a first main-switch, a second main-switch and N branch-switches. The first LED module comprises N first LED units. The second LED module comprises N second LED units. The first main-switch is coupled to the N first LED units. The second main-switch is coupled to the N second LED units. The N branch-switches are coupled to the N first LED units and the N second LED units.

The above and other aspects of the invention will become better understood with regard to the following detailed description of the preferred but non-limiting embodiment(s). The following description is made with reference to the accompanying drawings.

### BRIEF DESCRIPTION OF THE DRAWINGS

FIG. 1 shows a diagram of the display device according to an embodiment;

FIG. 2 shows a circuit diagram of the display device of FIG. 1;

FIG. 3 shows a timing diagram of signals controlling the first LED module and the second LED module of the display device of FIG. 1; and

FIG. 4 shows a circuit diagram of a display device according to another embodiment.

### DETAILED DESCRIPTION OF THE INVENTION

Detailed descriptions of the invention are disclosed below with a number of embodiments. However, the disclosed embodiments are for explanatory and exemplary purposes only, not for limiting the scope of protection of the invention. Similar/identical designations are used to indicate similar/identical elements.

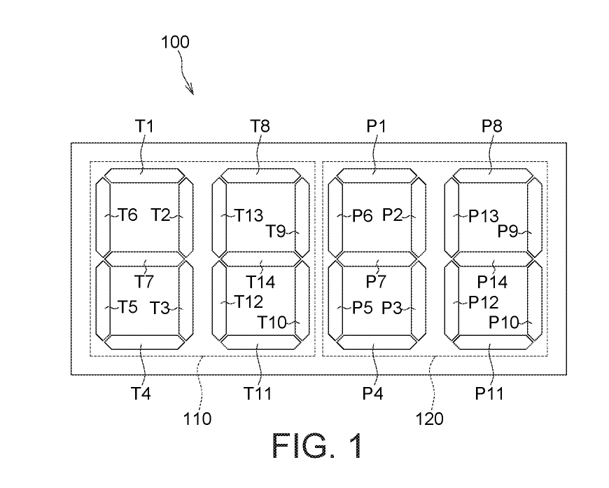

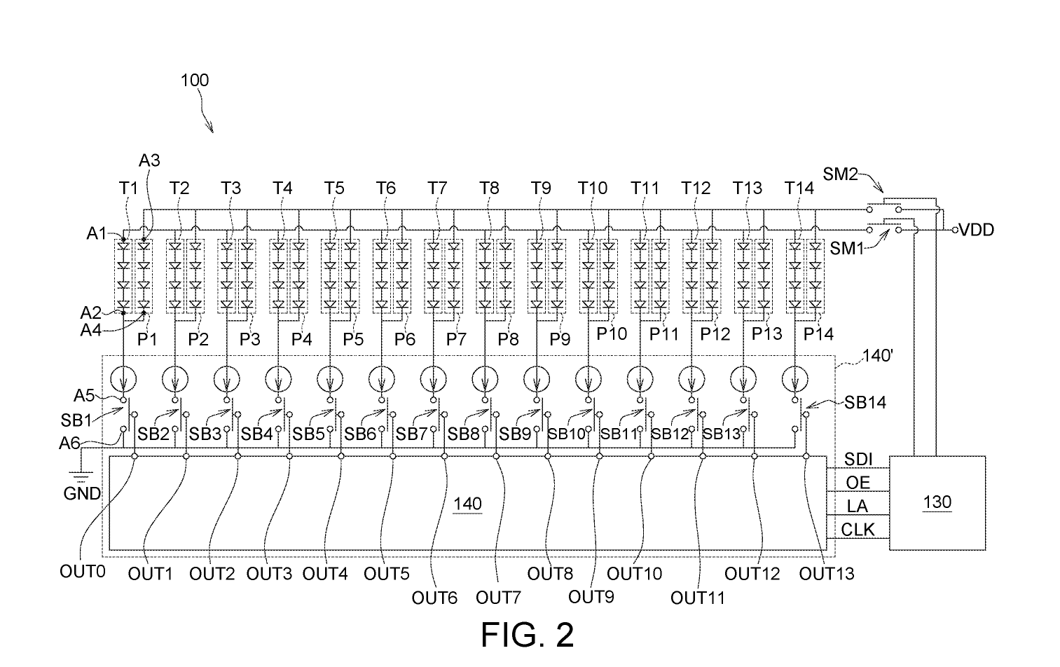

FIG. 1 shows a diagram of the display device 100 according to an embodiment, and FIG. 2 shows a circuit diagram of the display device 100 of FIG. 1.

As shown in FIGS. 1 and 2, the display device 100 includes a first LED (Light-emitting diode) module 110, a second LED module 120, a first main-switch SM1, a second main-switch SM2, a number of branch-switches SB1-SB14, a controller 130 and an LED driver 140. In an embodiment, the branch-switches SB1-SB14, the LED driver 140 and a number of constant-current sources may be integrated into one LED driver integrated circuit (IC) 140′. In another embodiment, the controller 130 and the LED driver 140 may be integrated into one control circuit.

In the present embodiment, the display device 100 is, for example, a traffic light device, the first LED module 110 is a first set of seven-segment display, and the second LED module 120 is a second set of seven-segment display. The first LED module 110 and the second LED module 120 may emit light of identical color or different color. For example, the first LED module 110 may emit one of green light and red light, and the second LED module 120 may emit another of green light and red light.

As shown in FIGS. 1 and 2, the first LED module 110 includes a number of first LED units T1-T14, and the second LED module 120 includes a number of second LED units P1-P14. As shown in FIG. 1, the first LED units T1-T14 are disposed to form number segments of a first set of segment display, wherein the first set of segment display includes two seven-segment displays. The second LED units P1-P14 are disposed to form number segments of a second set of segment display, wherein the second set of segment display includes two seven-segment displays.

In the present embodiment, the number of the first LED units T1-T14 is 14, and the number of the second LED units P1-P14 is 14, for example. The number of the branch-switches SB1-SB14 is equal to the number of the first LED units T1-T14 and the number of the second LED units P1-P14. In addition, the number of the branch-switches SB1-SB14 may be equal to the number of output ports of the LED driver 140, such that just one LED driver 140 can control all branch-switches.

As shown in FIG. 2, the first main-switch SM1 couples the first LED module 110 to the voltage supply VDD, and the second main-switch SM2 couples the second LED module 120 to the voltage supply VDD. One of the first LED units T1-T14 and one of the second LED units P1-P14 are coupled to one terminal of the corresponding branch-switch whose another terminal is coupled to a ground potential GND, for example.

Furthermore, one of the first LED units T1-T14 has a first terminal A1 and a second terminal A2, and one of the second LED units P1-P14 has a third terminal A3 and a fourth terminal A4, wherein the first terminal A1 is coupled to the first main-switch SM1, the third terminal A3 is coupled to the second main-switch SM2, and the second terminal A2 and the fourth terminal A4 are coupled to one of the branch-switches SB1-SB14. In addition, one of the branch-switches SB1-SB14 has a fifth terminal A5 and a sixth terminal A6, wherein the fifth terminal A5 is coupled to one of the first LED units T1-T14 of the first LED module 110 and one of the second LED units P1-P14 of the second LED module 120, and the sixth terminal A6 is coupled to the ground potential GND. Other of the first LED units T1-T14, other of the second LED units P1-P14 and other of the branch-switches SB1-SB14 have similar features, and it is not repeated here.

The controller 130 is, for example, a Micro Control Unit (MCU). The controller 130 can selectively turn on one of the first main-switch SM1 and the second main-switch SM2 and turn off another of the first main-switch SM1 and the second main-switch SM2. In other words, in the present embodiment, when the first main-switch SM1 is turned on, the second main-switch SM2 is turned off, or when second main-switch SM2 is turned on, the first main-switch SM1 is turned off. The controller 130 can control at least one of the branch-switches SB1-SB14 to turn on or turn off for controlling the LED units (T1-T14 or P1-P14) coupled to the turned on main-switch (SM1 or SM2) to emit light.

For example, when the first main-switch SM1 is turned on, the branch-switches SB1-SB14 are used to control the LED units T1-T14 of the first LED module 110, and when the second main-switch SM2 is turned on, the branch-switches SB1-SB14 are used to control the LED units P1-P14 of the second LED module 120. The branch-switches SB1-SB14 are shared by the first LED module 110 and the second LED module 120. As a result, the total number of the branch-switches need for the first LED module 110 and the second LED module 120 are reduced by using the first main-switch SM1 and the second main-switch SM2, comparing to the implementation that the first LED module 110 and the second LED module 120 are controlled by different sets of branch-switches.

The first LED module 110 and the second LED module 120 are not limited to seven-segment display. In another embodiment, the first LED units T1-T14 and the second LED units P1-P14 may be arranged in different pattern for displaying, for example, number, letter, word, and/or symbol. In addition, the number of the first LED units T1-T14 and the second LED units P1-P14 may be more or less than 14 in practice.

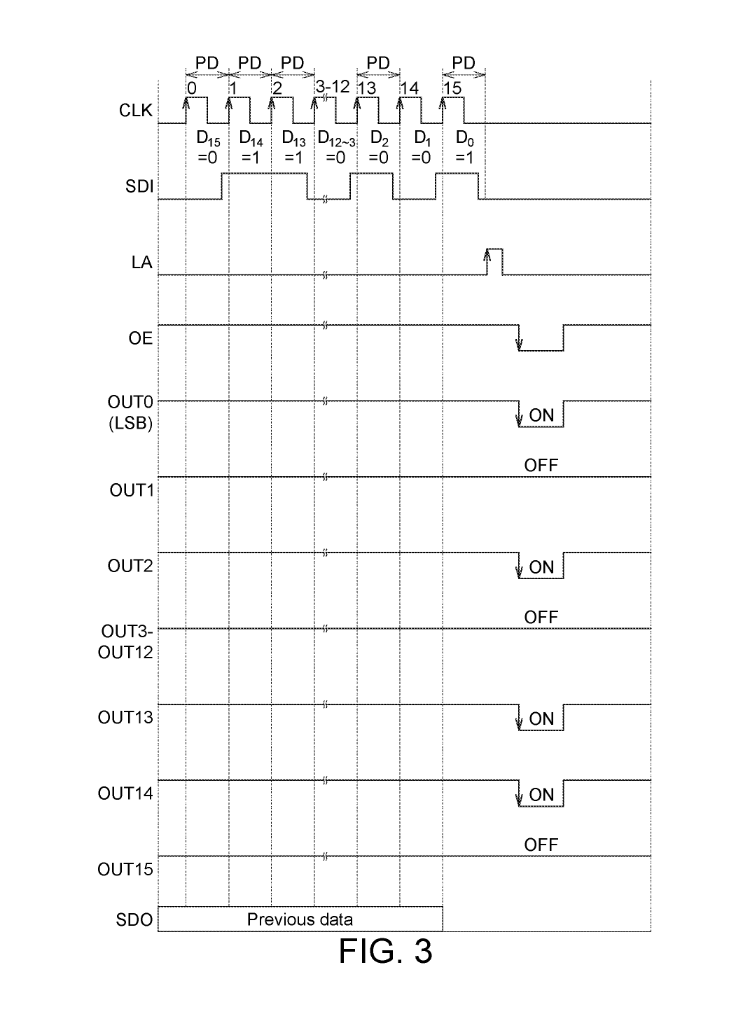

FIG. 3 shows a timing diagram of signals controlling the first LED module 110 and the second LED module 120 of the display device 100 of FIG. 1.

The branch-switches SB1-SB14 may be controlled by the controller 130 through the LED driver 140, while the first main-switch SM1 and the second main-switch SM2 may be directly controlled by the controller 130 (as shown in FIG. 2) or indirectly controlled by the controller 130 through the LED driver 140.

The controller 130 may output a clock signal CLK having a number of periods PD and a SDI (Serial digital interface) signal to the LED driver 140. The SDI signal transmits data of 16 bits sequentially during the 16 cycles (16 periods) of the clock signal CLK, for example. The LED driver 140 determines which branch-switch is required to turn on by sampling the SDI signal according to the clock signal CLK. After all of the data are output completely by SDI signal, the controller 130 enables an LA signal (high level) which is output to the LED driver 140. Then, the controller 130 enables an OE signal (low level) which is output to the LED driver 140 to instruct the LED driver 140 to control the branch-switches SB1-SB14 to be turned on or turned off. Then, the LED driver 140 outputs a number of control signals to the branch-switches SB1-14 through a number of output ports OUT0-OUT13. The control signal having a low level can turn on the corresponding branch-switch, and the control signal with high level can turn off the corresponding branch-switch, for example.

As shown in FIG. 3, if it is the first main-switch SM1 turned on by the controller 130, according to the SDI signal, the branch-switch SB14 (coupled to the OUT13 of the LED driver 140), the branch-switch SB3 (coupled to the OUT2 of the LED driver 140) and the branch-switch SB1 (coupled to the OUT0 of the LED driver 140) are turned on. Consequentially, the first LED units T14, T3 and T1 coupled to the branch-switch SB14, SB3 and SB1 respectively emit light. Besides, if it is the second main-switch SM2 turned on by the controller 130, the second LED unit P14, P3 and P1 coupled to the branch-switch SB14, SB3 and SB1 respectively emit light.

In addition, as shown in FIG. 3, the controller 130 may output a SDO signal to another LED driver through the signal SDO outputted by the LED driver 140 to control another display device to display identical number. The aforementioned another display device may include the structures similar or identical to that of the display device 100.

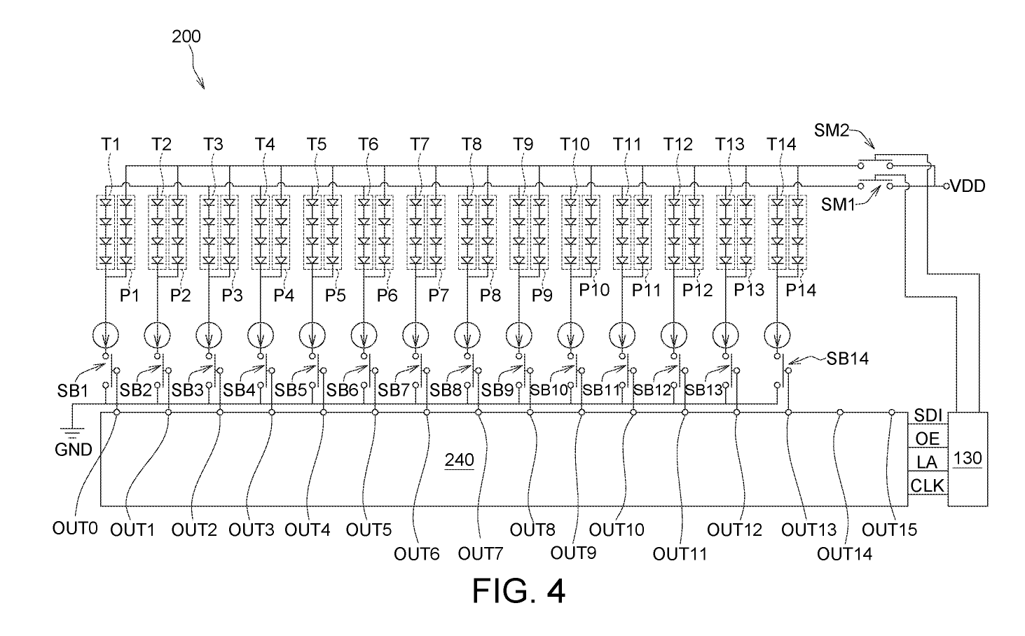

FIG. 4 shows a circuit diagram of a display device 200 according to another embodiment. The display device 200 includes the first LED module 110, the second LED module 120, the first main-switch SM1, the second main-switch SM2, the branch-switches SB1-SB14, the controller 130 and a LED driver 240.

In the present embodiment, the number of the branch-switches SB1-SB14 is less than the number of output ports OUT0-OUT15 of the LED driver 240. For example, the number of output ports OUT0-OUT15 of the LED driver 240 is 16, and the number of the branch-switches SB1-SB14 is 14, such that just one LED driver 240 can control all branch-switches.

In the present embodiment, the total number of the branch-switches SB1-SB14 and the main-switches SM1-SM2 is equal to that of the output ports OUT0-OUT15 of the LED driver 240. For example, the number of output ports of the LED driver 240 is 16, and the total number of the branch-switches SB1-SB14 and the main-switches SM1-SM2 is also 16. Alternatively, the total number of the branch-switches SB1-SB14 and the main-switches SM1-SM2 may be less than that of the output ports of the LED driver 240.

In addition, the branch-switches SB1-SB14, the LED driver 240 and a number of constant-current sources may be integrated into one LED driver IC. In another embodiment, the controller 130 and the LED driver 240 may be integrated into one control circuit.

To sum up, the display device of an embodiment includes a first main-switch, a second main-switch, a first LED module coupled to the first main-switch and including N first LED units, a second LED module coupled to the second main-switch and including N second LED units, and N branch-switches, wherein N is a positive integer being equal to or greater than 2. One terminal of one branch-switch is coupled to one of the first LED units and one of the second LED units. As a result, at least one of the first LED units may be controlled to emit light by turning on the corresponding branch-switches when the first main-switch is turned on. Similarly, at least one of the second LED units may be controlled to emit light by turning on the corresponding branch-switches when the second main-switch is turned on. In an embodiment, the LED units of each LED module may be arranged in various patterns to display number, letter, word, symbol, etc. The display device may be a traffic light, a counter, an indicator, a billboard, a signboard, etc. In another embodiment, the branch-switches may be controlled by the LED driver, while the first main-switch and the second main-switch may be controlled by the controller or the LED driver. By using the first main-switch and the second main-switch, the number of the branch-switches is reduced and the number of LED driver is also reduced, which saves the cost for the display device.

While the invention has been described by way of example and in terms of the preferred embodiment(s), it is to be understood that the invention is not limited thereto. On the contrary, it is intended to cover various modification and similar arrangements and procedures, and the scope of the appended claims therefore should be accorded the broadest interpretation so as to encompass all such modification and similar arrangements and procedures.

What is claimed is:

1. A display device, comprising:
a first light-emitting diode (LED) module comprising a plurality of first LED units;
a second LED module comprising a plurality of second LED units;
a first main-switch coupled to the first LED units;
a second main-switch coupled to the second LED units; and
a plurality of branch-switches coupled to the first LED units and the second LED units.

2. The display device according to claim 1, wherein each of the first LED units has a first terminal and a second terminal, and each of the second LED units has a third terminal and a fourth terminal; the first terminal is coupled to the first main-switch, the third terminal is coupled to the second main-switch, and the second terminal and the fourth terminal are coupled to one of the branch-switches.

3. The display device according to claim 1, wherein one of the branch-switches has a fifth terminal and a sixth terminal, the fifth terminal is coupled to the first LED module and the second LED module, and the sixth terminal is coupled to a ground potential.

4. The display device according to claim 1, wherein the number of the first LED units, the number of the second LED units and the number of the branch-switches are equal.

5. The display device according to claim 1, further comprising:
a LED driver coupled to the branch-switches and having a plurality of output ports;
wherein the number of the branch-switches is equal to or less than the number of the output ports.

6. The display device according to claim 1, further comprising:
a LED driver coupled to the branch-switches and having a plurality of output ports;
wherein the total number of the branch-switches, the first main-switch and the second main-switch is equal to or less than the number of the output ports.

7. The display device according to claim 1, further comprising:
a controller coupled to the first main-switch and the second main-switch, and configured to selectively turn on one of the first main-switch and the second main-switch and turn off another of the first main-switch and the second main-switch.

8. The display device according to claim 1, wherein the first LED module is a first set of segment display, and the second LED module is a second set of segment display.

9. The display device according to claim 8, wherein the first set of segment display includes two seven-segment displays, and the second set of segment display includes two seven-segment displays.

10. A display device, comprising:
a first LED module comprising N first LED units;
a second LED module comprising N second LED units;
a first main-switch coupled to the N first LED units;
a second main-switch coupled to the N second LED units; and
N branch-switches coupled to the N first LED units and the N second LED units;
wherein N is a positive integer being equal to or greater than 2.

11. The display device according to claim 10, further comprising:
a LED driver coupled to the branch-switches and having a plurality of output ports;
wherein N is equal o or less than the number of the output ports.

12. The display device according to claim 10, further comprising:
a LED driver coupled to the branch-switches and having a plurality of output ports;
wherein the total number of the branch-switches, the first main-switch and the second main-switch is equal to or less than the number of the output ports.
